(19) United States
(12) Patent Application Publication
(10) Pub. No.: US 2012/0127445 A1
(43) Pub. Date: May 24, 2012

(54) ISOLATION SYSTEM FOR AN OPTICAL ELEMENT OF AN EXPOSURE APPARATUS

(76) Inventors: Akimitsu Ebihara, Osaka (JP); Yi-Ping Hsin, Dublin, CA (US); Kunitomo Fukai, Sawa-gun (JP); Hideyuki Hashimoto, Saitama-shi (JP); Bausan Yuan, San Jose, CA (US)

(21) Appl. No.: 12/949,130

(22) Filed: Nov. 18, 2010

(51) Int. Cl. G03F 7/20; G03B 27/54; G02B 7/00

(52) U.S. Cl. 355/67; 359/822; 359/813; 355/77

(57) ABSTRACT

An optical isolation assembly (30) for reducing the transmission of vibration from an optical barrel (25) to an optical element assembly (28) includes an optical mover assembly (256), a first measurement system (258), a second measurement system (260), and a control system (24). The optical mover assembly (256) moves, positions and supports the optical element assembly (28) relative to the optical barrel (25). The first measurement system (258) generates one or more first measurement signals that relate to the relative position between the optical element assembly (28) and the optical barrel (25). The second measurement system (260) generates one or more second measurement signals that relate to the absolute movement of the optical element assembly (28) along the first axis. The control system (24) controls the optical mover assembly (256) utilizing the first measurement signals and the second measurement signals.

### BACKGROUND

Exposure apparatuses for semiconductor processing are commonly used to transfer images from a reticle onto a semiconductor wafer during semiconductor processing. A typical exposure apparatus includes an illumination source, a reticle stage assembly that positions a reticle, an optical assembly, a wafer stage assembly that positions a semiconductor wafer, a measurement system, and a control system. With this design, images from the reticle are transferred to the semiconductor wafer. The size of the images and features within the images transferred onto the wafer from the reticle are extremely small.

As is known, some of the components of the exposure apparatus generate vibration that can reduce the quality of the images that are transferred onto the wafer. For example, vibration transferred to the optical assembly can adversely influence the quality of the features that are transferred to the semiconductor wafer.

### SUMMARY

The present invention is directed to an optical isolation assembly for reducing the transmission of vibration from an optical barrel to an optical element assembly. In one embodiment, the optical isolation assembly includes an optical mover assembly, a first measurement system, a second measurement system, and a control system. The optical mover assembly moves and positions the optical element assembly relative to the optical barrel along a first axis. The first measurement system generates one or more first measurement signals that relate to the relative position between the optical element assembly and the optical barrel along the first axis. The second measurement system generates one or more second measurement signals that relate to the absolute movement of the optical element assembly along the first axis. The control system controls the optical mover assembly utilizing the first measurement signals and the second measurement signals.

As an overview, in certain embodiments, because the control system utilizes both the first measurement signals and the second measurement signals, the control system can control the optical mover assembly with improved accuracy, and thus, the position of the optical element assembly can be maintained with improved accuracy.

In certain embodiments, the optical mover assembly also moves the optical element assembly along a second axis that is orthogonal to the first axis, along a third axis that is orthogonal to the first axis and the second axis, and about the first, second, and third axes. In one embodiment, the optical mover assembly can include three spaced apart movers, and each mover can be a voice coil type mover that moves the optical element assembly with two degrees of freedom. With this design, the three movers can cooperate to move the optical element assembly with six degrees of freedom.

Further, each mover can include a first mover component that is coupled to the optical barrel, and a second mover component that is coupled the optical element assembly. Moreover, the second mover component can be spaced apart from the first mover component so that vibration from the optical barrel is not transferred via the movers to the optical element assembly.

In certain embodiments, the first measurement system is designed so that the first measurement signals also relate to the position of the optical element assembly relative to the optical barrel along the second and third axes, and about the first, second, and third axes. Further, in certain embodiments, the second measurement system is designed so that the second measurement signals also relate to the absolute movement of the optical element assembly along the second and third axes, and about the first, second, and third axes.

Additionally, the optical isolation assembly can include a support that supports the weight of the optical element assembly relative to the optical barrel along the first axis, while allowing the optical mover assembly to move the optical element assembly relative to the optical barrel. With this design, less power is required by the optical mover assembly to support the weight of the optical element assembly.

In one embodiment, the support includes a first magnetic component that is coupled to the optical barrel and a second magnetic component that is coupled to the optical element assembly. In this design, the second magnetic component is spaced apart from the first magnetic component, and the second magnetic component is repulsed by the first magnetic component. In another embodiment, the support defines a fluid chamber that supports the optical element assembly.

The present invention is also directed to an optical assembly comprising an optical element assembly, an optical barrel, and the optical isolation assembly described above. Moreover, the present invention is directed to an exposure apparatus for transferring an image to a substrate. Further, the present invention is directed to a method for manufacturing a wafer that includes the steps of providing a substrate and transferring an image to the substrate with the exposure apparatus described herein.

In yet another embodiment, the present invention is directed to a method for reducing the transmission of vibration from an optical barrel to an optical element assembly. In this embodiment, the method includes the steps of (i) supporting the optical element assembly relative to the optical barrel along the first axis with an optical mover assembly; (ii) generating a first measurement signal that relates to the position of the optical element assembly relative to the optical barrel along the first axis with a first measurement system; (iii) generating a second measurement signal that relates to the absolute movement of the optical element assembly along the first axis with a second measurement system; and (iv) controlling the optical mover assembly utilizing the first measurement signal and the second measurement signal with a control system.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a simplified schematic illustration of an exposure apparatus having features of the present invention;

FIG. 2 is a simplified perspective illustration of one embodiment of an optical element assembly, an optical base, and an optical isolation assembly having features of the present invention;

FIG. 3 is a simplified perspective view of another embodiment of an optical element assembly, and a portion of an optical isolation assembly having features of the present invention;

FIG. 4 is a simplified perspective view of still another embodiment of an optical element assembly, and a portion of an optical isolation assembly having features of the present invention;

FIG. 5A is a simplified side view of a support having features of the present invention;

FIG. 5B is a simplified perspective view of the support of FIG. 5A;

FIG. 6 is a simplified cross-sectional view of another embodiment of a support having features of the present invention;

FIG. 7A is a flow chart that outlines a process for manufacturing a device in accordance with the present invention; and

FIG. 7B is a flow chart that outlines device processing in more detail.

### DESCRIPTION

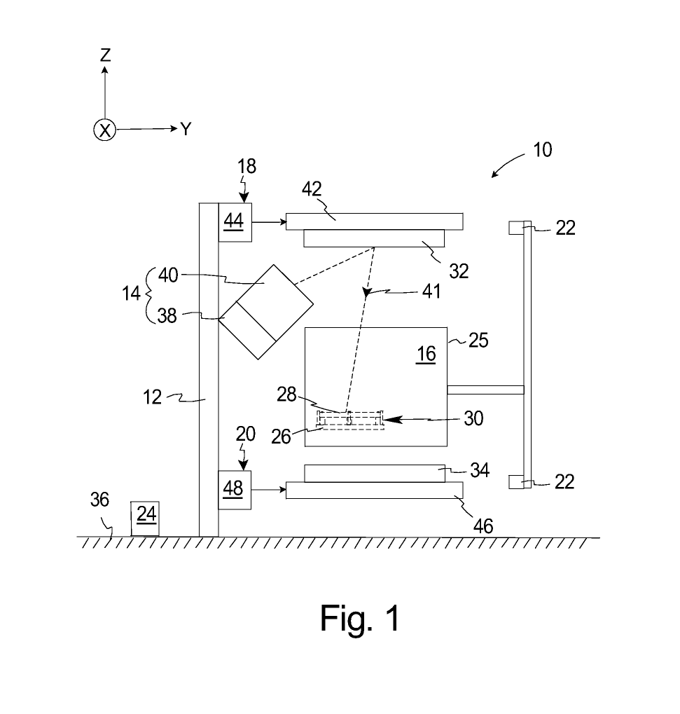

FIG. 1 is a schematic illustration of a precision assembly, namely an exposure apparatus 10 having features of the present invention. The exposure apparatus 10 includes an apparatus frame 12, an illumination system 14 (irradiation apparatus), a projection optical assembly 16, a reticle stage assembly 18, a wafer stage assembly 20, a sensor system 22, and a control system 24. The design of the components of the exposure apparatus 10 can be varied to suit the design requirements of the exposure apparatus 10.

As an overview, in FIG. 1, the projection optical assembly 16 includes an optical barrel 25, one or more optical bases 26 (only one is illustrated in phantom) that are fixedly secured to the optical barrel 25, one or more optical element assemblies 28 (only one is illustrated in phantom), and one or more optical isolation assemblies 30 (only one is illustrated in phantom) that isolate and position the optical element assemblies 28 relative to the optical bases 26 and the optical barrel 25. As provided herein, the optical isolation assembly 30 is uniquely designed to inhibit the transfer of vibration to the optical element assembly 28 and to position the optical element assembly 28 with improved accuracy. As a result thereof, the exposure apparatus 10 is capable of manufacturing higher precision devices, such as higher density, semiconductor wafers.

A number of Figures include an orientation system that illustrates an X axis, a Y axis that is orthogonal to the X axis and a Z axis that is orthogonal to the X and Y axes. It should be noted that these axes can also be referred to as the first, second and third axes.

The exposure apparatus 10 is particularly useful as a lithographic device that transfers a pattern (not shown) of an integrated circuit from a reticle 32 onto a semiconductor wafer 34. The exposure apparatus 10 mounts to a mounting base 36, e.g., the ground, a base, or floor or some other supporting structure.

There are a number of different types of lithographic devices. For example, the exposure apparatus 10 can be used as a scanning type photolithography system that exposes the pattern from the reticle 32 onto the wafer 34 with the reticle 32 and the wafer 34 moving synchronously. Alternatively, the exposure apparatus 10 can be a step-and-repeat type photolithography system that exposes the reticle 32 while the reticle 32 and the wafer 34 are stationary.

In one embodiment, the exposure apparatus 10 is an extreme ultra-violet (“EUV”) type exposure apparatus.

However, the use of the exposure apparatus 10 provided herein is not limited to a photolithography system for semiconductor manufacturing. The exposure apparatus 10, for example, can be used as an LCD photolithography system that exposes a liquid crystal display device pattern onto a rectangular glass plate or a photolithography system for manufacturing a thin film magnetic head.

The apparatus frame 12 is rigid and supports the components of the exposure apparatus 10. The apparatus frame 12 illustrated in FIG. 1 supports the stage assemblies 18, 20, the optical assembly 16 and the illumination system 14 above the mounting base 36.

In one embodiment, the illumination system 14 includes an illumination source 38 and an illumination optical assembly 40. The illumination source 38 emits an energy beam 41 (irradiation) of light energy. The illumination optical assembly 40 guides the beam 41 of light energy from the illumination source 38 to the reticle 32. The beam 41 illuminates selectively different portions of the reticle 32 and exposes the wafer 34. In FIG. 1, the illumination source 38 is illustrated as directing the energy beam 41 at the bottom of the reticle 32 and the energy beam 41 can be reflected off of the reticle towards the projection optical assembly 16. Alternatively, in certain embodiments, the energy beam 41 can be directed through the reticle 32.

The illumination source 38 can be a g-line source (436 nm), an i-line source (365 nm), a KrF excimer laser (248 nm), an ArF excimer laser (193 nm) or a F₂ laser (157 nm). Alternatively, the illumination source 38 can generate charged particle beams such as an x-ray or an electron beam. For instance, in the case where an electron beam is used, thermionic emission type lanthanum hexaboride (LaB₆) or tantalum (Ta) can be used as a cathode for an electron gun and the electron beam 41 is in the extreme ultra-violet wavelength. Furthermore, in the case where an electron beam is used, the structure could be such that either a mask is used or a pattern can be directly formed on a substrate without the use of a mask.

The projection optical assembly 16 guides the light energy 41 to the wafer 34. Depending upon the design of the exposure apparatus 10, the optical assembly 16 can magnify or reduce the image illuminated on the reticle 32. The optical assembly 16 need not be limited to a reduction system. It could also be a 1× or magnification system.

When far ultra-violet rays such as the excimer laser is used, glass materials such as quartz and fluorite that transmit far ultra-violet rays can be used in the optical assembly 16. When the F₂ type laser or x-ray is used, the optical assembly 16 can be either catadioptric or refractive. Alternatively, for an EUV energy beam 41, the optical elements 28 are reflective (e.g. mirrors) and the optical path for the EUV beam 41 should be in a vacuum.

The reticle stage assembly 18 holds and positions the reticle 32 relative to the optical assembly 16 and the wafer 34. Somewhat similarly, the wafer stage assembly 20 holds and positions the wafer 34 with respect to the projected image of the illuminated portions of the reticle 32. The design of each stage assembly 18, 20 can be varied to suit the movement requirements of the exposure apparatus 10. In FIG. 1, the reticle stage assembly 18 includes a reticle stage 42 that retains the reticle 32 and a reticle mover assembly 44 that moves and positions the reticle stage 42 and the reticle 32 relative to the rest of the exposure apparatus 10. Somewhat similarly, the wafer stage assembly 20 includes a wafer stage 46 that retains the wafer 34 and a wafer mover assembly 48 that moves and positions the wafer stage 46 and the wafer 34 relative to the rest of the exposure apparatus 10.

The sensor system 22 monitors the position of (i) the reticle stage 42 and the reticle 32 relative to the optical assembly 16 or some other reference, and (ii) the wafer stage 46 and the wafer 34 relative to the optical assembly 16 or some other reference. With this information, the control system 24 can control the reticle stage assembly 18 to precisely position the reticle 32 and the wafer stage assembly 20 to precisely position the wafer 34. For example, the sensor system 22 can utilize multiple laser interferometers, encoders, and/or other measuring devices.

The control system 24 is electrically connected to the optical isolation assembly 30, the reticle stage assembly 18, the wafer stage assembly 20, and the sensor system 22. The control system 24 receives information from the sensor system 22 and controls the stage assemblies 18, 20 to precisely position the reticle 32 and the wafer 34. Further, the control system 24 controls the operation of the optical isolation assembly 30 to precisely position and isolate the optical element assembly 28. The control system 24 can include one or more processors and circuits.

Additionally, the exposure apparatus 10 can include one or more additional isolation systems (not shown) that isolate the projection optical assembly 16 from the other components of the exposure apparatus 10.

A photolithography system (an exposure apparatus) according to the embodiments described herein can be built by assembling various subsystems, including each element listed in the appended claims, in such a manner that prescribed mechanical accuracy, electrical accuracy, and optical accuracy are maintained. In order to maintain the various accuracies, prior to and following assembly, every optical system is adjusted to achieve its optical accuracy. Similarly, every mechanical system and every electrical system are adjusted to achieve their respective mechanical and electrical accuracies. The process of assembling each subsystem into a photolithography system includes mechanical interfaces, electrical circuit wiring connections and air pressure plumbing connections between each subsystem. There is also a process where each subsystem is assembled prior to assembling a photolithography system from the various subsystems. Once a photolithography system is assembled using the various subsystems, a total adjustment is performed to make sure that accuracy is maintained in the complete photolithography system. Additionally, it is desirable to manufacture an exposure system in a clean room where the temperature and cleanliness are controlled.

This invention can be utilized in an immersion type exposure apparatus with taking suitable measures for a liquid. For example, PCT Patent Application WO 99/49504 discloses an exposure apparatus in which a liquid is supplied to the space between a substrate (wafer) and a projection lens system in exposure process. As far as is permitted, the disclosures in WO 99/49504 are incorporated herein by reference.

Further, this invention can be utilized in an exposure apparatus that comprises two or more substrate and/or reticle stages. In such apparatus, the additional stage may be used in parallel or preparatory steps while the other stage is being used for exposing. Such a multiple stage exposure apparatus are described, for example, in Japan Patent Application Disclosure No. 10-163099 as well as Japan Patent Application Disclosure No. 10-214783 and its counterparts U.S. Pat. No. 6,341,007, No. 6,400,441, No. 6,549,269, and No. 6,590,634. Also it is described in Japan Patent Application Disclosure No. 2000-505958 and its counterparts U.S. Pat. No. 5,969,411 as well as U.S. Pat. No. 6,208,407. As far as is permitted, the disclosures in the above-mentioned U.S. patents, as well as the Japan Patent Applications, are incorporated herein by reference.

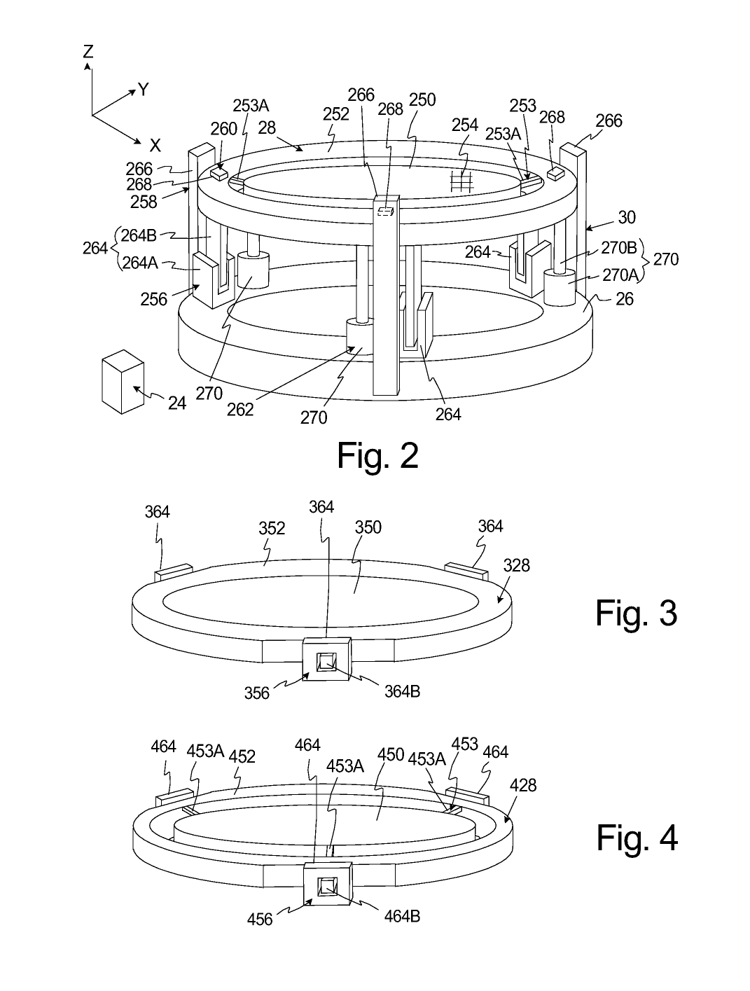

FIG. 2 is a perspective illustration of the optical base 26, the optical element assembly 28, and the optical isolation assembly 30 from FIG. 1. The control system 24 is also illustrated in FIG. 2. The optical components 26, 28, 30 can be part of the projection optical assembly 16 (illustrated in FIG. 1) of the exposure apparatus 10 illustrated in FIG. 1. Alternatively, for example, the optical components 26, 28, 30 can be used in the illumination optical assembly 40 (illustrated in FIG. 1) or another type of optical assembly.

The optical base 26 is rigid and can be secured to the optical barrel 25 (illustrated in FIG. 1) of the optical assembly 16 (illustrated in FIG. 1). In FIG. 2, the optical base 26 is generally annular ring shaped. Alternatively, the optical base 26 can be disk shaped or have a different configuration. Moreover, in FIG. 2, the optical base 26 is illustrated as being positioned below the optical element assembly 28. Alternatively, the optical base 26 can be positioned above the optical element assembly 28.

The optical element assembly 28 directs the energy beam 41 (illustrated in FIG. 1). In FIG. 2, the optical element assembly 28 includes an optical element 250, an element mount 252, and an element connector assembly 253 that secures the optical element 250 to the element mount 252. Alternatively, for example, the optical element assembly 28 can be designed without the element mount 252 and/or without the element connector assembly 253.

In one embodiment, the optical element 250 is circular disk shaped and includes a reflective coating 254 (illustrated with cross-hatching) that is designed to reflect an EUV energy beam 41. Alternatively, the reflective coating 254 can reflect light at a wavelength other than EUV or the optical element 250 can be designed to transmit the energy beam 41.

Further, in FIG. 2, the element mount 252 is generally annular ring shaped and encircles and retains the optical element 250. Alternatively, the element mount 252 can have a configuration different than that illustrated in FIG. 2.

The element connector assembly 253 secures the optical element 250 to the element mount 252. In one embodiment, the element connector assembly 253 includes three, equally spaced apart connectors 253A (only two are illustrated in FIG. 2). For example, each connector 253A can be a flexure that extends between the optical element 250 and the element mount 252. With this design, the connectors 253A can couple the optical element 250 to the element mount 252 in a kinematic fashion so that bending of the element mount 252 is not transferred to the optical element 250. Additionally, or alternatively, each connector 253A can include a mover that adjusts the position of the optical element 250 relative the element mount 252.

The optical isolation assembly 30 isolates and precisely positions the optical element assembly 28. For EUV lithography systems 10, the reflective optical elements 250 are very position sensitive. In one embodiment, the optical isolation assembly 308 isolates the optical element 250 from vibration.

Further, during operation of the EUV lithography systems 10, a portion of the extreme ultraviolet radiation is absorbed by the optical elements 250. The absorbed ultraviolet radiation heats the illuminated regions of the optical elements 250 and causes the temperature in the illuminated regions to rise to a greater extent than the temperature in non-illuminated regions of the optical elements 250. The increase in temperature in the illuminated regions causes the optical element 250 to distort. This can blur the image that is transferred onto the wafer 34 (illustrated in FIG. 1). As provided herein, the optical isolation assembly 30 can be used to adjust the position of the optical element 250 to approximately compensate for the thermal distortion produced by the illumination beam. Additionally, the optical isolation assembly 30 can be used to adjust the position of the optical element 250 to correct other deficiencies with the image that is being transferred onto the wafer 34.

In one embodiment, the optical isolation assembly 30 includes an optical mover assembly 256, a first measurement system 258, a second measurement system 260, and a support assembly 262 that cooperate to isolate and accurately position the optical element assembly 28. Alternatively, the optical isolation assembly 30 can have fewer or more components than illustrated in FIG. 2. For example, in certain embodiments, the optical isolation assembly 30 can be designed without the support assembly 262.

The optical mover assembly 256 moves the optical element assembly 28 relative to the optical base 26. In one embodiment, the optical mover assembly 256 includes three, equally spaced apart movers 264 that each move with two degrees of freedom so that the three movers 264 cooperate to move the optical element assembly 28 with six degrees of freedom, namely along the X, Y and Z axes, and about the X, Y, and Z axes. Alternatively, for example, the optical mover assembly 256 can be designed to move the optical element assembly 28 with fewer than three degrees of freedom.

The design of each mover 264 can be varied to suit the movement and isolation requirements of the optical element assembly 28. In the embodiment illustrated in FIG. 2, each mover 264 is a two degree of freedom, voice coil type motor and includes a first mover component 264A that is fixedly secured to the optical base 26, and a second mover component 264B that is fixedly secured to the optical element assembly 28. In this embodiment, for each of the movers 264, one of the mover components 264A, 264B includes one or more magnet arrays and the other mover component 264B, 264A includes one or more conductor arrays. Further, each magnet array includes one or more magnets, and each conductor array includes one or more conductors.

With this design, electrical current (not shown) is supplied to the conductor(s) in each conductor array by the control system 24. For each mover 264, the electrical current in the conductor(s) interact with the magnetic field(s) from the magnets in the magnet array. For each mover 264, this causes a force (Lorentz force) between the conductors and the magnets that can be used to selectively move the optical element assembly 28 with two degrees of freedom.

It should be noted that with the mover 264 illustrated in FIG. 2, the second mover component 264B is spaced apart from and not in contact with the first mover component 264A. As a result thereof, vibration from the optical base 26 is not transferred via the first mover component 264A to the second mover component 264B.

The first measurement system 258 generates one or more first measurement signals that relate to the relative movement between the optical element assembly 28 and the optical base 26. In the embodiment illustrated in FIG. 2, the first measurement system 258 includes three, equally spaced apart position sensors 266 that monitor the relative movement between the optical element assembly 28 and the optical base 26 along the X, Y, and Z axes, and about the X, Y, and Z axes. Additionally or alternatively, the first measurement system 258 can be designed to monitor relative movement between the optical element assembly 28 and the optical base 26 with less than six degrees of freedom.

In one non-exclusive example, each position sensor 266 can be a linear encoder, such as a laserscale that monitors movement along two axes. With this design, the three position sensors 266 can be used to monitor six degrees of freedom. Alternatively, each position sensor 266 can be a laser interferometer or another type of measuring device.

The second measurement system 260 provides one or more second measurement signals that relate to the absolute movement of the optical element assembly 28. In one non-exclusive embodiment, the second measurement system 260 includes three spaced apart absolute sensors 268 that monitor the absolute movement of the optical element assembly 28 along the X, Y, and Z axes, and about the X, Y, and Z axes. Additionally or alternatively, the second measurement system 260 can be designed to monitor absolute movement of the optical element assembly 28 with less than six degrees of freedom.

In one non-exclusive example, each absolute sensor 268 can be a two axis accelerometer. With this design, the three absolute sensors 268 can be used to monitor six degrees of freedom. Alternatively, for example, each absolute sensor 268 can be a three axis accelerometer. With this design, the two absolute sensors 268 can be used to monitor six degrees of freedom. As another non-exclusive example, three, two-axis short-distance position encoders can be utilized.

The control system 24 directs voltage to and individually controls each of the movers 264 based on both the first measurement signals and the second measurement signals. Because the control system 24 utilizes both measurement signals, the optical isolation assembly 30 is better able to isolate and accurately position the optical element assembly 28.

For example, in the situation in which vibration is being transferred to the optical base 26 via the optical barrel 25 (illustrated in FIG. 1), because the first measurement system 258 monitors the relative position between the optical base 26 and the optical element assembly 28, the first measurement system 258 will not be able to determine if the optical element assembly 28 is being moved or if the optical base 26 is being moved. Thus, in this situation, if only the first measurement system 258 is being utilized, the control system 24 will not be able to accurately isolate the optical element assembly 28. Alternatively, with the present invention, in these types of situations, the second measurement signals can be utilized to determine if the optical element assembly 28 is being moved. Thus, using the measurement signals from both of the measurement systems 258, 260, the control system 24 will be better able to control the optical mover assembly 256.

For example, in one embodiment, the six degree of freedom control system will utilize signals from three, two degree of freedom sensors and convert the signals to six degree of freedom measurement (e.g. along the X, Y, and Z axes, and about the X, Y, and Z axes).

The support assembly 262 supports the weight of the optical element assembly 28 along the Z axis so that the optical mover assembly 256 does not have to be driven to support the weight of the optical element assembly 28 while still allowing the optical mover assembly 256 to move and position the optical element assembly 28. This reduces the amount of heat generated by the optical mover assembly 256. The design of the support assembly 262 can be varied. In FIG. 2, the support assembly 262 includes three equally spaced apart supports 270, and each support 270 includes a first support component 270A that is fixedly secured to the optical base 26, and a second support component 270B that is fixedly secured to the optical element assembly 28. For example, each support 270 can be a fluid type suspension. Non-exclusive examples of suitable supports 270 are described below.

In certain embodiments, the optical mover assembly 256 and the support assembly 262 are coupled to the optical element assembly 28 in a kinematic fashion to inhibit deformation of the optical element 250.

FIG. 3 is a simplified perspective view of another embodiment of an optical element assembly 328, and an optical mover assembly 356. The optical base 26, the measurement systems 258, 260, and the support assembly 262 are not illustrated in FIG. 3. In this embodiment, the optical element assembly 328 includes the optical element 350 and the element mount 352 molded directly onto the optical element 350. Moreover, in this embodiment, the optical mover assembly 356 includes the three spaced apart movers 364, and the second mover component 364B for each mover 364 is fixedly secured to the perimeter of the element mount 352.

FIG. 4 is a perspective view of another embodiment of the optical element assembly 428 and the optical mover assembly 456. The optical base 26, the measurement systems 258, 260, and the support assembly 262 are not illustrated in FIG. 4. In this embodiment, the optical element assembly 428 includes the optical element 450, the element mount 452 that encircles the optical element 450, and an element connector assembly 453 that connects the optical element 450 to the element mount 452 in a kinematic fashion so that deformation of the element mount 452 does not cause deformation to the optical element 450. For example, the element connector assembly 453 can include one or more (e.g. three) spaced apart connectors 453A (e.g. flexures) that each extends between the optical element 450 and the element mount 452.

Further, in FIG. 4, the optical mover assembly 456 includes the three spaced apart movers 464, and the second mover component 464B for each mover 464 is fixedly secured to the perimeter of the element mount 452.

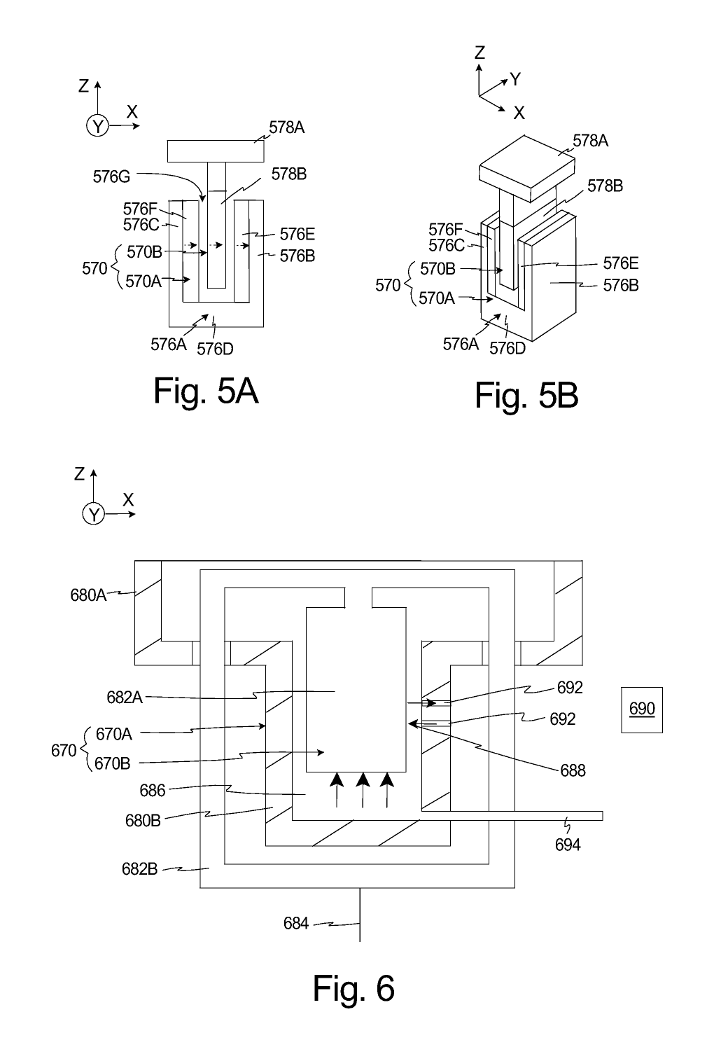

FIG. 5A is a simplified side view and FIG. 5B is a simplified perspective view of one embodiment of a support 570 having features of the present invention. In this embodiment, the support 570 is a magnetic support that includes a first magnetic support component 570A and a second magnetic support component 570B that is spaced apart from the first magnetic support component 570A. In this embodiment, the second magnetic component 570B is repulsed by the first magnetic component 570A. With this design, the support 570 can support the weight of the optical element assembly 28 without the use of electrical power and thus without the generation of heat that can adversely influence the optical element assembly 28.

In this embodiment, one of the magnetic components 570A, 570B is coupled to the optical base 26 (illustrated in FIG. 2) and the other magnetic component 570B, 570A is coupled to the optical element assembly 28 (illustrated in FIG. 2). Further, in FIGS. 5A and 5B, the first magnetic support component 570A includes (i) a generally inverted U shaped housing 576A that includes a first side section 576B, a second side second 576C that is spaced apart from the first side section 576B, and a center section 576D, (ii) a first magnet array 576E that is secured to the first side section 576B, and (iii) a second magnet array 576F that is secured to the second side section 576C. Further, the first magnet array 576E is spaced apart a magnet gap 576G from the second magnet array 576F. Moreover, the second magnetic support component 578 includes a generally inverted T shaped housing 578A and a magnet assembly 578B that is positioned in the magnet gap 576G between magnet arrays 576E, 576F of the first magnetic support component 576. In this embodiment, the magnet arrays 576E, 576F and the magnet assembly 576B can each include one or more permanent magnets.

It should be noted that dashed arrows in FIG. 5A illustrate one non-exclusive example of the magnetic orientation of the magnetic components 570A, 570B.

FIG. 6 is a simplified cross-sectional view of another embodiment of a support 670 that can be used to support the optical element assembly 28 (illustrated in FIG. 2). In this embodiment, the support 670 is a fluid type support that includes a first support component 670A that is coupled to the optical barrel 25 (illustrated in FIG. 1), a second support component 670B that is spaced apart from the first support component 670A, and a suspension flexure 684 (e.g. a wire) that couples the second support component 670B to the optical element assembly 28. Further, in this embodiment, the support 670 is positioned above the optical element assembly 28.

In FIG. 6, the first support component 670A includes an upper frame 680A that is secured to the optical barrel 25, and a cylindrical shaped lower frame 680B. Moreover, in FIG. 6, the second support component 670B includes (i) a support piston 682A that fits within the cylindrical shaped lower frame 680B and cooperates with the lower frame 680B to define a support chamber 686, and (ii) a connector assembly 682B that connects the support piston 682 to the suspension flexure 684.

Further, in this embodiment, a seal 688 (illustrated as arrows) seals the interface between the support piston 682A and the lower frame 680B and allows the support piston 682A to move within the lower frame 680B. For example, a fluid source 690 can be connected via tubes 692 (two are illustrated in FIG. 6) to the interface between the support piston 682A and the lower frame 680B to create a vacuum fluid type bearing/seal between the support piston 682A and the lower frame 680B that guides and allows the support piston 682A to move relative to the lower frame 680B, and that seals the interface between the support piston 682A and the lower frame 680B. Alternatively, a different type of seal 688 can be utilized.

Moreover, in one embodiment, the support chamber 686 is in fluid communication with the atmosphere via one or more conduits 694 (only one is illustrated in FIG. 6). With this design, if the support 670 is in a vacuum environment (e.g. positioned within the optical barrel 25 that is subjected to a vacuum), the pressure below the support piston 682A is at atmospheric pressure and pressure above the support piston 682 is at a vacuum. Thus, the pressure is greater below the support piston 682 than above the support piston 682. As a result thereof, the support 670 can be used to support the weight of the optical element assembly 28.

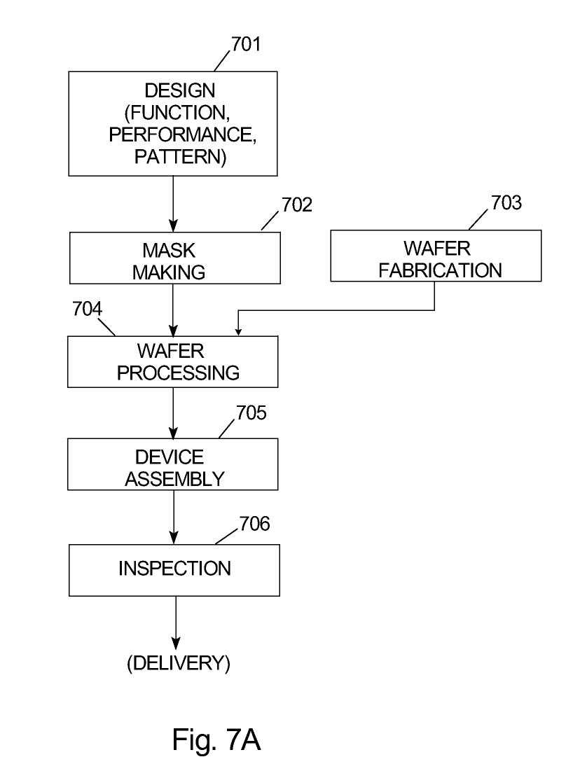

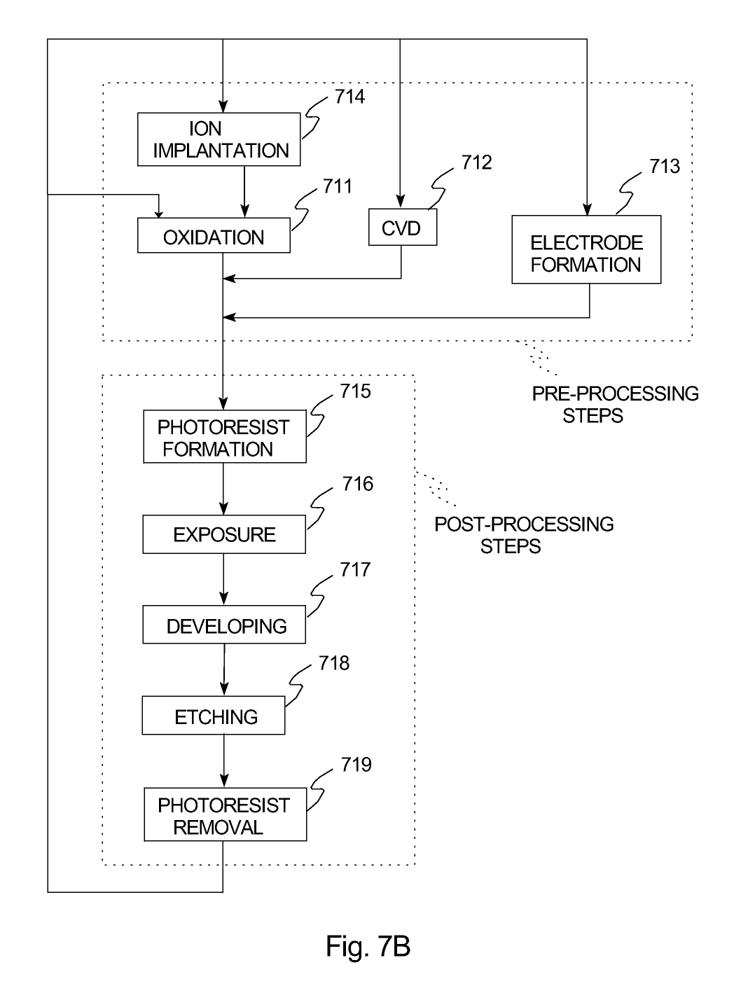

It should be noted that a somewhat similar support 670 is described in Japanese Publication Number JP2006/140366, entitled “Projection Optical System and Exposure Apparatus”. As far a permitted, the contents of Japanese Publication Number JP2006/140366 are incorporated herein by reference. Semiconductor devices can be fabricated using the above described systems, by the process shown generally in FIG. 7A. In step 701 the device's function and performance characteristics are designed. Next, in step 702, a mask (reticle) having a pattern is designed according to the previous designing step, and in a parallel step 703 a wafer is made from a silicon material. The mask pattern designed in step 702 is exposed onto the wafer from step 703 in step 704 by a photolithography system described hereinabove in accordance with the present invention. In step 705 the semiconductor device is assembled (including the dicing process, bonding process and packaging process), finally, the device is then inspected in step 706.

FIG. 7B illustrates a detailed flowchart example of the above-mentioned step 704 in the case of fabricating semiconductor devices. In FIG. 7B, in step 711 (oxidation step), the wafer surface is oxidized. In step 712 (CVD step), an insulation film is formed on the wafer surface. In step 713 (electrode formation step), electrodes are formed on the wafer by vapor deposition. In step 714 (ion implantation step), ions are implanted in the wafer. The above mentioned steps 711-714 form the preprocessing steps for wafers during wafer processing, and selection is made at each step according to processing requirements.

At each stage of wafer processing, when the above-mentioned preprocessing steps have been completed, the following post-processing steps are implemented. During post-processing, first, in step 715 (photoresist formation step), photoresist is applied to a wafer. Next, in step 716 (exposure step), the above-mentioned exposure device is used to transfer the circuit pattern of a mask (reticle) to a wafer. Then in step 717 (developing step), the exposed wafer is developed, and in step 718 (etching step), parts other than residual photoresist (exposed material surface) are removed by etching. In step 719 (photoresist removal step), unnecessary photoresist remaining after etching is removed.

Multiple circuit patterns are formed by repetition of these preprocessing and post-processing steps.

While the current invention is disclosed in detail herein, it is to be understood that it is merely illustrative of the presently preferred embodiments of the invention and that no limitations are intended to the details of construction or design herein shown other than as described in the appended claims.

What is claimed is:

1. An optical isolation assembly for reducing the transmission of vibration from an optical barrel to an optical element assembly along a first axis, the optical isolation assembly comprising:
an optical mover assembly that moves the optical element assembly relative to the optical barrel along the first axis;
a first measurement system that generates a first measurement signal that relates to the position of the optical element assembly relative to the optical barrel along the first axis;
a second measurement system that generates a second measurement signal that relates to the movement of the optical element assembly along the first axis; and
a control system that controls the optical mover assembly utilizing the first measurement signal and the second measurement signal.

2. The optical isolation assembly of claim 1 wherein the first measurement system includes an encoder and wherein the second measurement system includes an accelerometer.

3. The optical isolation assembly of claim 1 wherein the optical mover assembly also moves the optical element assembly about a second axis that is orthogonal to the first axis, and about a third axis that is orthogonal to the first axis and the second axis; wherein the first measurement signal also relates to the position of the optical element assembly relative to the optical barrel about the second axis and about the third axis; and wherein the second measurement signal also relates to the movement of the optical element assembly about the second axis, and about the third axis.

4. The optical isolation assembly of claim 1 wherein the optical mover assembly includes three spaced apart movers, and each mover includes a first mover component that is coupled to the optical barrel, and a second mover component that is coupled the optical element assembly, the second mover component being spaced apart from the first mover component; and wherein each mover moves the optical element assembly with two degrees of freedom.

5. The optical isolation assembly of claim 1 wherein the optical mover assembly also moves the optical element assembly along a second axis that is orthogonal to the first axis, along a third axis that is orthogonal to the first axis and the second axis, about the first axis, about the second axis, and about the third axis; wherein the first measurement signal also relates to the position of the optical element assembly relative to the optical barrel along the second and third axes, and about the first, second and third axes; and wherein the second measurement signal also relates to the movement of the optical element assembly along the second and third axes, and about the first, second and third axes.

6. The optical isolation assembly of claim 1 further comprising a support that supports the weight of the optical element assembly relative to the optical barrel along the first axis, the support assembly allowing the optical mover assembly to move the optical element assembly relative to the optical barrel.

7. The optical isolation assembly of claim 6 wherein the support includes a first magnetic component that is coupled to the optical barrel and a second magnetic component that is coupled to the optical element assembly, and wherein the second magnetic component is spaced apart from the first magnetic component and wherein the second magnetic component is repulsed by the first magnetic component.

8. The optical isolation assembly of claim 6 wherein the support defines a fluid chamber that supports the optical element assembly.

9. An optical assembly comprising an optical element assembly, an optical barrel, and the optical isolation assembly of claim 1 that secures the optical element assembly to the optical barrel and that inhibits the transfer of vibration from the optical barrel to the optical element assembly.

10. An exposure apparatus for transferring an image to a substrate, the exposure apparatus comprising an illumination system that generates an energy beam and the optical assembly of claim 9 that directs the energy beam.

11. The exposure apparatus of claim 10 wherein the illumination system includes an EUV illumination source that generates an energy beam that is in the extreme ultra-violet spectrum, and wherein the optical element assembly includes a reflective optical element.

12. A method for manufacturing a wafer, the method comprising the steps of providing a substrate and transferring an image to the substrate with the exposure apparatus of claim 10.

13. An optical assembly for an exposure apparatus, the optical assembly comprising:
an optical barrel;
an optical element assembly; and
an optical isolation assembly that couples the optical element assembly to the optical barrel and that reduces the transmission of vibration from an optical barrel to an optical element assembly along a first axis, along a second axis that is orthogonal to the first axis, along a third axis that is orthogonal to the first and second axes, about the first axis, about the second axis, and about the third axis, the optical isolation assembly including (i) an optical mover assembly moves the optical element assembly along the first, second and third axes, and about the first second, and third axes; (ii) a first measurement system generates a first measurement signal that relates to the position of the optical element assembly relative to the optical barrel along the first, second and third axes, and about the first, second and third axes; (iii) a second measurement system generates a second measurement signal that relates to the absolute movement of the optical element assembly along the first, second and third axes, and about the first, second and third axes; and (iv) a control system that controls the optical mover assembly utilizing the first measurement signal and the second measurement signal.

14. The optical assembly of claim 13 wherein the first measurement system includes an encoder and wherein the second measurement system includes an accelerometer.

15. The optical isolation assembly of claim 13 wherein the optical mover assembly includes three spaced apart voice coil movers, and each mover includes a first mover component that is coupled to the optical barrel, and a second mover component that is coupled the optical element assembly, the second mover component being spaced apart from the first mover component; and wherein each voice coil mover moves the optical element assembly with two degrees of freedom.

16. The optical isolation assembly of claim 13 further comprising a support that supports the weight of the optical element assembly relative to the optical barrel, the support assembly allowing the optical mover assembly to move the optical element assembly relative to the optical barrel.

17. An EUV exposure apparatus for transferring an image to a substrate, the EUV exposure apparatus comprising an illumination system that generates an energy beam in the extreme ultra-violet spectrum, and the optical assembly of claim 13 that directs the energy beam; wherein the optical element assembly includes a reflective optical element.

18. A method for manufacturing a wafer, the method comprising the steps of providing a substrate and transferring an image to the substrate with the EUV exposure apparatus of claim 17.

19. A method for reducing the transmission of vibration from an optical barrel to an optical element assembly along a first axis, the method comprising the steps of:
supporting the optical element assembly relative to the optical barrel along the first axis with an optical mover assembly;
generating a first measurement signal that relates to the position of the optical element assembly relative to the optical barrel along the first axis with a first measurement system;
generating a second measurement signal that relates to the absolute movement of the optical element assembly along the first axis with a second measurement system; and
controlling the optical mover assembly utilizing the first measurement signal and the second measurement signal with a control system.

20. The method of claim 19 wherein the step of supporting includes supporting the optical element assembly about a second axis that is orthogonal to the first axis, and about a third axis that is orthogonal to the first axis and the second axis; wherein the step of generating a first measurement signal includes the first measurement signal also relating to the position of the optical element assembly relative to the optical barrel about the second axis and about the third axis; and wherein the step of generating a second measurement signal includes the second measurement signal also relating to the movement of the optical element assembly about the second axis, and about the third axis.

21. The method of claim 19 wherein the step of supporting includes supporting the optical element assembly about a second axis that is orthogonal to the first axis, about a third axis that is orthogonal to the first axis and the second axis, along the second axis, along the third axis, and about the first axis; wherein the step of generating a first measurement signal includes the first measurement signal also relating to the position of the optical element assembly relative to the optical barrel about the first, second and third axes, and along the second and third axes; and wherein the step of generating a second measurement signal includes the second measurement signal also relating to the movement of the optical element assembly about the first, second and third axes, and along the second and third axes.

22. The method of claim 19 further comprising the step of supporting the weight of the optical element assembly relative to the optical barrel with a support assembly that allows the optical mover assembly to move the optical element assembly relative to the optical barrel.
